(19) United States
(12) Patent Application Publication
(10) Pub. No.: US 2011/0227216 A1
(43) Pub. Date: Sep. 22, 2011

(54) Under-Bump Metallization Structure for Semiconductor Devices

(75) Inventors: Ming-Hung Tseng, Toufen Township (TW); Chen-Shien Chen, Zhubei City (TW); Chen-Cheng Kuo, Chu-Pei City (TW); Chih-Hua Chen, Jhubei City (TW); Ching-Wen Hsiao, Banqiao City (TW)

(73) Assignee: Taiwan Semiconductor Manufacturing Company, Ltd., Hsin-Chu (TW)

(21) Appl. No.: 12/725,322

(22) Filed: Mar. 16, 2010

(51) Int. Cl. H01L 23/498; H01L 21/60

(52) U.S. Cl. 257/737; 438/614; 257/E23.068; 257/E21.508

(57) ABSTRACT

An under-bump metallization (UBM) structure for a semiconductor device is provided. A passivation layer is formed over a contact pad such that at least a portion of the contact pad is exposed. A protective layer, such as a polyimide layer, may be formed over the passivation layer. The UBM structure, such as a conductive pillar, is formed over the underlying contact pad such that the underlying contact pad extends laterally past the UBM structure by a distance large enough to prevent or reduce cracking of the passivation layer and or protective layer.

### TECHNICAL FIELD

This disclosure relates generally to semiconductor devices and, more particularly, to under-bump metallization structures for semiconductor devices.

### BACKGROUND

Since the invention of the integrated circuit (IC), the semiconductor industry has experienced continued rapid growth due to continuous improvements in the integration density of various electronic components (i.e., transistors, diodes, resistors, capacitors, etc.). For the most part, this improvement in integration density has come from repeated reductions in minimum feature size, which allows more components to be integrated into a given area.

The past few decades have also seen many shifts in semiconductor packaging that have impacted the entire semiconductor industry. The introduction of surface-mount technology (SMT) and ball grid array (BGA) packages were generally important steps for high-throughput assembly of a wide variety of IC devices, while at the same time allowing for reduction of the pad pitch on the printed circuit board. Conventionally packaged ICs have a structure basically interconnected by fine gold wire between metal pads on the die and electrodes spreading out of molded resin packages. On the other hand, some CSP or BGA packages rely on bumps of solder to provide an electrical connection between contacts on the die and contacts on a substrate, such as a packaging substrate, a printed circuit board (PCB), another die/wafer, or the like. Other CSP or BGA packages utilize a solder ball or bump placed onto a conductive pillar, relying on the soldered joint for structural integrity. The different layers making up the interconnection typically have different coefficients of thermal expansion (CTEs). As a result, a relatively large stress derived from this difference is exhibited on the joint area, which often causes cracks to form.

### SUMMARY

An under-bump metallization (UBM) structure for a semiconductor device is provided. A substrate having a contact pad formed thereon is provided. A passivation layer is formed over a contact pad such that at least a portion of the contact pad is exposed. A protective layer, such as a polyimide layer, may be formed over the passivation layer. The UBM structure, such as a conductive pillar, is formed over the underlying contact pad such that the underlying contact pad extends laterally past the UBM structure by a distance sufficiently large enough to reduce or eliminate cracking in the passivation and/or protective layers.

Other embodiments are disclosed.

### BRIEF DESCRIPTION OF THE DRAWINGS

For a more complete understanding of the embodiments, and the advantages thereof, reference is now made to the following descriptions taken in conjunction with the accompanying drawings, in which:

FIG. 1 is a plan view of contact pads of a semiconductor device in accordance with an embodiment; and

FIGS. 2-6 illustrate various intermediate stages of a method of forming a semiconductor device having an under-bump metallization structure in accordance with an embodiment.

### DETAILED DESCRIPTION

The making and using of the embodiments of the disclosure are discussed in detail below. It should be appreciated, however, that the embodiments provide many applicable inventive concepts that can be embodied in a wide variety of specific contexts. The specific embodiments discussed are merely illustrative of specific ways to make and use the embodiments, and do not limit the scope of the disclosure.

Embodiments described herein relate to the use of under-bump metallization (UBM) for use with semiconductor devices. As will be discussed below, embodiments are disclosed that utilize a UBM structure for the purpose of attaching one substrate to another substrate, wherein each substrate may be a die, wafer, printed circuit board, packaging substrate, or the like, thereby allowing for die-to-die, wafer-to-die, wafer-to-wafer, die or wafer to printed circuit board or packaging substrate, or the like. Throughout the various views and illustrative embodiments, like reference numerals are used to designate like elements.

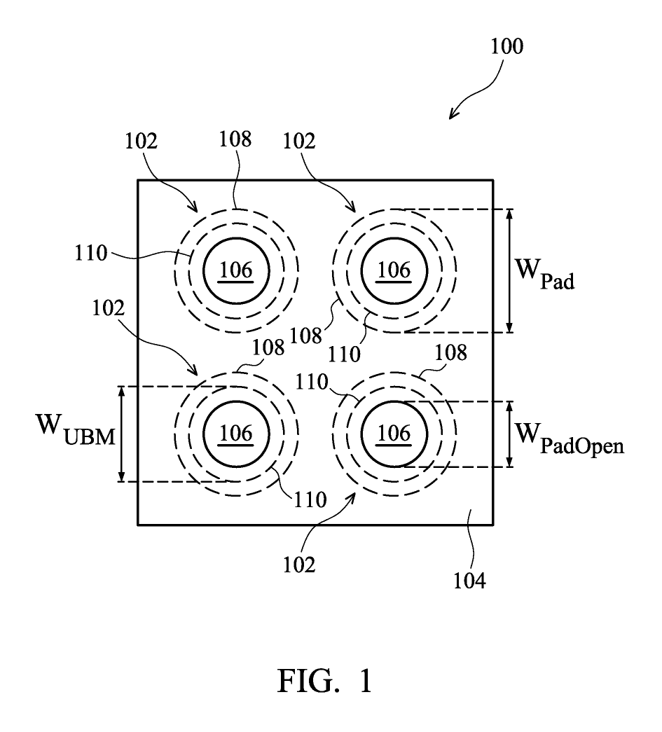

FIG. 1 is a plan view of a portion of a substrate 100 having external contacts 102 formed thereon in accordance with an embodiment. The exterior surface of the substrate 100 is covered with a protective layer 104, such as a polyimide layer, to protect the substrate from environmental contaminants. Within the protective layer 104 are shown openings 106 having a width W_{PadOpen}, which expose the underlying conductive pad 108 having a width W_{Pad}.

Also shown in FIG. 1 is an outline for a UBM 110 having a width W_{UBM}. The UBM 110 may be, for example, a copper or other conductive material pillar structure that provides an electrical connection to the underlying conductive pad 108. The UBM 110 may subsequently be connected to another substrate, such as a die, wafer, printed circuit board, packaging substrate, or the like.

While the trend has been to make devices smaller and smaller as discussed above, it has been found that decreasing the size may exert stress in certain areas and possibly cause devices to fail. For example, it has been found that forming a device in which the difference in the width W_{UBM} of the UBM 110 and the width W_{Pad} of the underlying conductive pad 108 is small, such as 2 μm or less, may exert sufficient stress on a passivation layer (not shown, see below) and/or the protective layer 104 to cause one or both to crack. Contrary to the current trends in the industry, however, it has been also been found that if the difference between the width W_{UBM} and W_{Pad} is 6 μm or more (e.g., extending 3 μm laterally in each direction), increasing rather than shrinking the width of the W_{Pad} relative to the width W_{UBM}, may reduce the stress and cracking of the protective layer and/or the passivation layer may be reduced and/or eliminated.

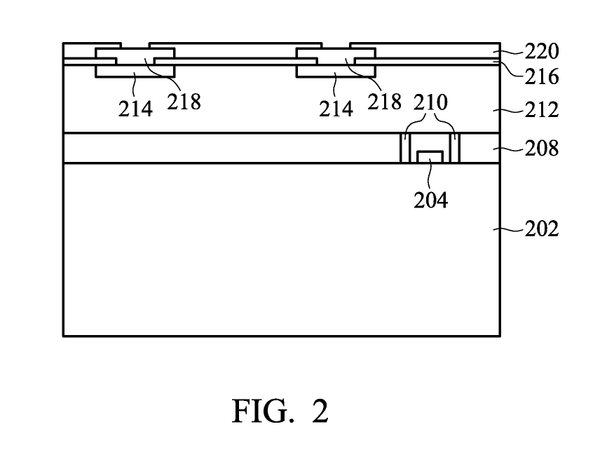

FIGS. 2-6 illustrate various intermediate stages of a method of forming a semiconductor device such as that discussed above with reference to FIG. 1 in accordance with an embodiment. Referring first to FIG. 2, a portion of a substrate 202 having electrical circuitry 204 formed thereon is shown in accordance with an embodiment. The substrate 202 may comprise, for example, bulk silicon, doped or undoped, or an active layer of a semiconductor-on-insulator (SOI) substrate. Generally, an SOI substrate comprises a layer of a semiconductor material, such as silicon, formed on an insulator layer. The insulator layer may be, for example, a buried oxide (BOX) layer or a silicon oxide layer. The insulator layer is provided on a substrate, typically a silicon or glass substrate. Other substrates, such as a multi-layered or gradient substrate may also be used.

Electrical circuitry 204 formed on the substrate 202 may be any type of circuitry suitable for a particular application. In an embodiment, the electrical circuitry 204 includes electrical devices formed on the substrate 202 with one or more dielectric layers overlying the electrical devices. Metal layers may be formed between dielectric layers to route electrical signals between the electrical devices. Electrical devices may also be formed in one or more dielectric layers.

For example, the electrical circuitry 204 may include various N-type metal-oxide semiconductor (NMOS) and/or P-type metal-oxide semiconductor (PMOS) devices, such as transistors, capacitors, resistors, diodes, photo-diodes, fuses, and the like, interconnected to perform one or more functions. The functions may include memory structures, processing structures, sensors, amplifiers, power distribution, input/output circuitry, or the like. One of ordinary skill in the art will appreciate that the above examples are provided for illustrative purposes only to further explain applications of some illustrative embodiments and are not meant to limit the disclosure in any manner. Other circuitry may be used as appropriate for a given application.

Also shown in FIG. 2 is an inter-layer dielectric (ILD) layer 208. The ILD layer 208 may be formed, for example, of a low-K dielectric material, such as phosphosilicate glass (PSG), borophosphosilicate glass (BPSG), fluorinated silicate glass (FSG), SiOₓC_{y}, Spin-On-Glass, Spin-On-Polymers, silicon carbon material, compounds thereof, composites thereof, combinations thereof, or the like, by any suitable method known in the art, such as spinning, chemical vapor deposition (CVD), and plasma-enhanced CVD (PECVD). It should also be noted that the ILD layer 208 may comprise a plurality of dielectric layers.

Contacts, such as contacts 210, are formed through the ILD layer 208 to provide an electrical contact to the electrical circuitry 204. The contacts 210 may be formed, for example, by using photolithography techniques to deposit and pattern a photoresist material on the ILD layer 208 to expose portions of the ILD layer 208 that are to become the contacts 210. An etch process, such as an anisotropic dry etch process, may be used to create openings in the ILD layer 208. The openings may be lined with a diffusion barrier layer and/or an adhesion layer (not shown), and filled with a conductive material. In an embodiment, the diffusion barrier layer comprises one or more layers of TaN, Ta, TiN, Ti, CoW, or the like, and the conductive material comprises copper, tungsten, aluminum, silver, and combinations thereof, or the like, thereby forming the contacts 210 as illustrated in FIG. 2.

One or more inter-metal dielectric (IMD) layers 212 and the associated metallization layers (not shown) are formed over the ILD layer 208. Generally, the one or more IMD layers 212 and the associated metallization layers are used to interconnect the electrical circuitry 204 to each other and to provide an external electrical connection. The IMD layers 212 may be formed of a low-K dielectric material, such as FSG formed by PECVD techniques or high-density plasma CVD (HDPCVD), or the like, and may include intermediate etch stop layers. Contacts 214 are provided in the uppermost IMD layer to provide external electrical connections.

It should be noted that one or more etch stop layers (not shown) may be positioned between adjacent ones of the dielectric layers, e.g., the ILD layer 208 and the IMD layers 212. Generally, the etch stop layers provide a mechanism to stop an etching process when forming vias and/or contacts. The etch stop layers are formed of a dielectric material having a different etch selectivity from adjacent layers, e.g., the underlying semiconductor substrate 202, the overlying ILD layer 208, and the overlying IMD layers 212. In an embodiment, etch stop layers may be formed of SiN, SiCN, SiCO, CN, combinations thereof, or the like, deposited by CVD or PECVD techniques.

A protective layer 216 may be formed of a dielectric material, such as SiN, a plasma-enhance oxide (PEOX), a plasma-enhanced SiN (PE-SiN), plasma-enhanced undoped silicate glass (PE-USG), or the like, and patterned over the surface of the uppermost IMD layer 212 to provide an opening over the contacts 214 and to protect the underlying layers from various environmental contaminants. Thereafter, conductive pads 218 are formed and patterned over the protective layer 216. The conductive pads 218 provide an electrical connection upon which a UBM structure, such as a copper pillar structure, may be formed for external connections. The conductive pads 218 may be formed of any suitable conductive materials, such as copper, tungsten, aluminum, silver, combinations thereof, or the like.

One or more passivation layers, such as passivation layer 220, are formed and patterned over the conductive pads 218 as illustrated in FIG. 2. The passivation layer 220 may be formed of a dielectric material, such as PE-USG, PE-SiN, combinations thereof, and/or the like, by any suitable method, such as CVD, PVD, or the like. In an embodiment, the passivation layer 220 has a thickness of about 10,000 Å to about 15,000 Å. In an embodiment, the passivation layer 220 comprises a multi-layer structure of 750 Å of SiN, 6,500 Å of PE-USG, and 6,000 A of PE-SiN.

One of ordinary skill in the art will appreciate that a single layer of conductive pads and a passivation layer are shown for illustrative purposes only. As such, other embodiments may include any number of conductive layers and/or passivation layers. Furthermore, it should be appreciated that one or more of the conductive layers may act as a redistribution layer (RDL) to provide the desired pin or ball layout.

Any suitable process may be used to form the structures discussed above and will not be discussed in greater detail herein. As one of ordinary skill in the art will realize, the above description provides a general description of the features of the embodiment and that numerous other features may be present. For example, other circuitry, liners, barrier layers, under-bump metallization configurations, and the like, may be present. The above description is meant only to provide a context for embodiments discussed herein and is not meant to limit the disclosure or the scope of any claims to those specific embodiments.

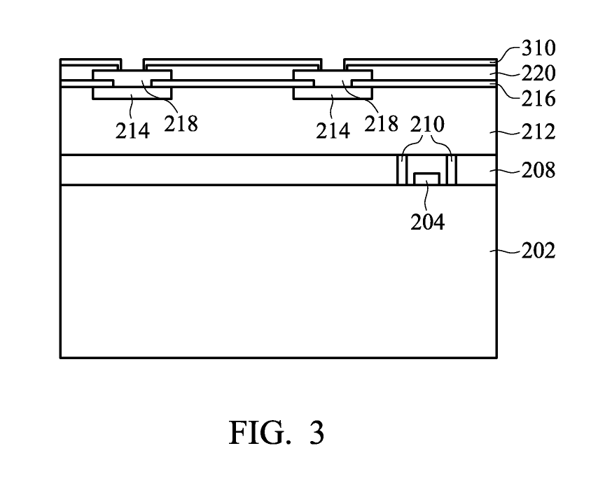

FIG. 3 illustrates a protective layer 310 formed and patterned over the passivation layer 220. The protective layer 310 may be, for example, a polyimide material formed by any suitable process, such as CVD, PVD, or the like. In an embodiment, the protective layer 310 has a thickness between about 2.5 μm and about 10 μm.

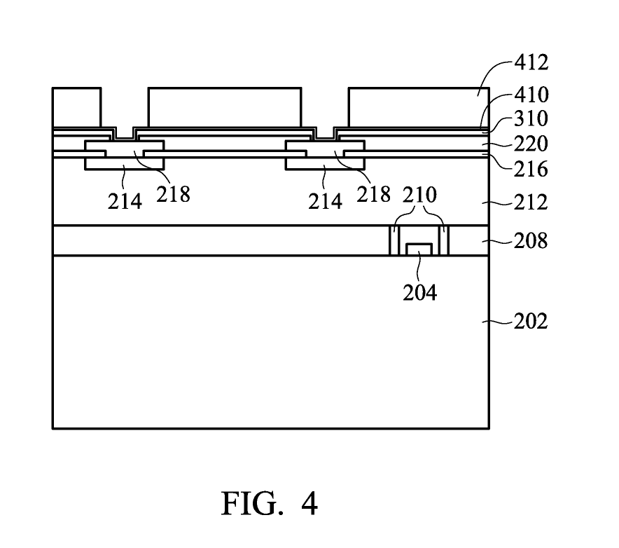

FIG. 4 illustrates a conformal seed layer 410 deposited over the surface of the protective layer 310. The seed layer 410 is a thin layer of a conductive material that aids in the formation of a thicker layer during subsequent processing steps. In an embodiment, the seed layer 410 may be formed by depositing a thin conductive layer, such as a thin layer of Cu, Ti, Ta, TiN, TaN, combinations thereof, or the like, using CVD or physical vapor deposition (PVD) techniques. For example, a layer of Ti is deposited by a PVD process to form a barrier film and a layer of Cu is deposited by a PVD process to form a seed layer.

Thereafter, as illustrated in FIG. 4, a patterned mask 412 is formed and patterned over the seed layer 410 in accordance with an embodiment. The patterned mask 412 defines the lateral boundaries of the conductive pillar to be subsequently formed as discussed in greater detail below. The patterned mask 412 may be a patterned photoresist mask, hard mask, a combination thereof, or the like.

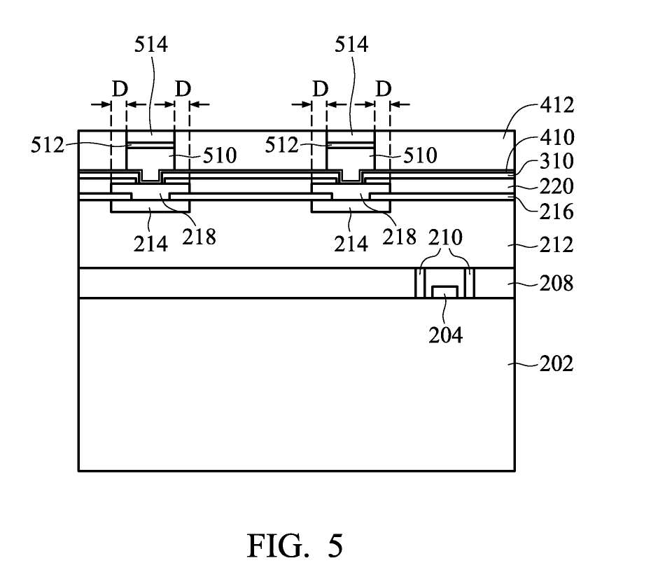

FIG. 5 illustrates the formation of a conductive pillar 510 in accordance with an embodiment. The conductive pillar 510 may be formed of any suitable conductive material, including Cu, Ni, Pt, Al, combinations thereof, or the like, and may be formed through any number of suitable techniques, including PVD, CVD, electrochemical deposition (ECD), molecular beam epitaxy (MBE), atomic layer deposition (ALD), electroplating, and the like. It should be noted that in some embodiments, such as those that deposit a conformal layer over the entire surface of the wafer (e.g., PVD and CVD), it may be desirable to perform an etching or planarization process (e.g., a chemical mechanical polishing (CMP)) to remove excess conductive material from the surface of the patterned mask 412. In an embodiment, the conductive pillar 510 has a thickness between about 20 μm and about 50 μm.

FIG. 5 also illustrates formation of an optional conductive cap layer 512 formed over the conductive pillar 510. As described in greater detail below, solder material will be formed over the conductive pillar 510. During the soldering process, an inter-metallic compound (IMC) layer (not shown) may be naturally formed at the joint between the solder material and the underlying surface. It has been found that some materials may create a stronger, more durable IMC layer than others. As such, it may be desirable to form a cap layer, such as the conductive cap layer 512, to provide an IMC layer having more desirable characteristics. For example, in an embodiment in which the conductive pillar 510 is formed of copper, a conductive cap layer 512 formed of nickel may be desirable. Other materials, such as Pt, Au, Ag, combinations thereof, or the like, may also be used. The conductive cap layer 512 may be formed through any number of suitable techniques, including PVD, CVD, ECD, MBE, ALD, electroplating, and the like.

Furthermore, FIG. 5 also illustrates formation of solder material 514. In an embodiment, the solder material 514 comprises SnPb, a high-Pb material, a Sn-based solder, a lead-free solder, or other suitable conductive material.

As discussed above, in an embodiment the dimensions and placement of the conductive pillar 510 relative to the conductive pads 218 is such that a distance D is 3 μm or greater. It has been found that forming a device in which the conductive pads 218 extend laterally past the outer boundary of the conductive pillar 510 by this amount may reduce the stress and cracking of the protective layer 310 and/or the passivation layer 220.

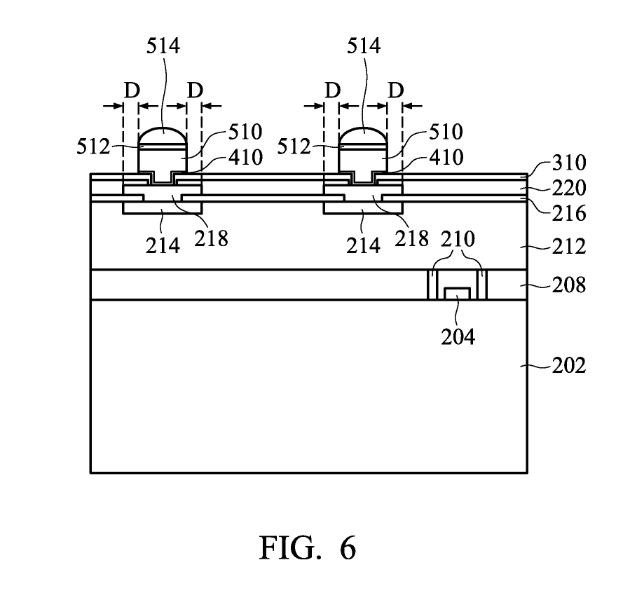

Thereafter, as illustrated in FIG. 6, the patterned mask 412 may be removed. In embodiments in which the patterned mask 412 is formed from photoresist materials, the photoresist may be stripped by, for example, a chemical solution such as a mixture of ethyl lactate, anisole, methyl butyl acetate, amyl acetate, cresol novolak resin, and diazo photoactive compound (referred to as SPR9), or another stripping process. A cleaning process, such as a wet dip in a chemical solution of phosphoric acid (H₃PO₄) and hydrogen peroxide (H₂O₂), referred to as DPP, with 2% hydrofluoric (HF) acid, or another cleaning process, may be performed to remove exposed portions of the seed layer 410 and any contaminants from the surface of the passivation layer 220.

Thereafter, a solder reflow process and other back-end-of-line (BEOL) processing techniques suitable for the particular application may be performed. For example, an encapsulant may be formed, a singulation process may be performed to singulate individual dies, wafer-level or die-level stacking, and the like, may be performed. It should be noted, however, that embodiments may be used in many different situations. For example, embodiments may be used in a die-to-die bonding configuration, a die-to-wafer bonding configuration, a wafer-to-wafer bonding configuration, die-level packaging, wafer-level packaging, or the like.

It should also be noted that other embodiments may not place the solder material on the conductive pillars 510 prior to attaching the substrate 202 to another substrate (not shown). In these other embodiments, the solder material may be placed on the other substrate and then the conductive pillars 510 on the substrate 202 are brought into contact with the solder material on the other substrate and a reflow process is performed to solder the two substrates together.

Although the embodiments and their advantages have been described in detail, it should be understood that various changes, substitutions and alterations can be made herein without departing from the spirit and scope of the embodiments as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the disclosure. Accordingly, the appended claims are intended to include within their scope such processes, machines, manufacture, compositions of matter, means, methods, or steps. In addition, each claim constitutes a separate embodiment, and the combination of various claims and embodiments are within the scope of the disclosure.

1. A semiconductor structure comprising:
a substrate comprising a conductive pad, the conductive pad having a first width; and
a pillar electrically coupled to the conductive pad, the pillar having a second width, the second width being a widest width of the pillar, the first width being about 6 μm or greater than the second width.

2. The semiconductor structure of claim 1, further comprising solder material on the pillar and in electrical contact with the conductive pad.

3. The semiconductor structure of claim 1, further comprising a capping layer on the pillar and in electrical contact with the conductive pad.

4. The semiconductor structure of claim 3, wherein the capping layer is formed of Ni, Pt, Au, or Ag.

5. The semiconductor structure of claim 1, further comprising a passivation layer overlying at least a part of the conductive pad.

6. The semiconductor structure of claim 5, further comprising a protective layer overlying the passivation layer.

7. The semiconductor structure of claim 6, wherein the protective layer is polyimide.

8. A semiconductor structure comprising:
a substrate comprising a conductive pad, the conductive pad having a first width; and
a pillar electrically coupled to the conductive pad, the pillar having a second width, the conductive pad extending laterally past an outermost surface of the pillar a distance of about 3 μm or greater.

9. The semiconductor structure of claim 8, further comprising solder material on the pillar and in electrical contact with the conductive pad.

10. The semiconductor structure of claim 8, further comprising a capping layer on the pillar.

11. The semiconductor structure of claim 10, wherein the capping layer is formed of Ni, Pt, Au, or Ag.

12. The semiconductor structure of claim 8, further comprising a passivation layer overlying at least a part of the conductive pad.

13. The semiconductor structure of claim 12, further comprising a protective layer overlying the passivation layer.

14. The semiconductor structure of claim 13, wherein the protective layer is polyimide.

15. A method of forming a semiconductor device, the method comprising:
providing a substrate having a conductive pad, the conductive pad having a first outer boundary;
forming a passivation layer over the substrate and the conductive pad, at least a portion of the conductive pad being exposed; and
forming a conductive pillar in electrical contact with the conductive pad, the conductive pillar having a second outer boundary, the second outer boundary being at least 3 μm from the first outer boundary in a plan view.

16. The method of claim 15, further comprising forming a capping layer over the conductive pillar.

17. The method of claim 16, wherein the capping layer is formed of Ni, Pt, Au, or Ag.

18. The method of claim 16, further comprising forming a solder material over the capping layer.

19. The method of claim 15, further comprising forming a solder material over the conductive pillar.
